(19) United States
(12) Patent Application Publication
(10) Pub. No.: US 2026/0321340 A1
(43) Pub. Date: Oct. 15, 2026

(54) PREDICTIVE MODEL FACILITATED CONCURRENT DEVICE MAINTENANCE

(71) Applicant: International Business Machines Corporation, Armonk, NY (US)

(72) Inventors: Gary A. Van Huben, Poughkeepsie, NY (US); Ryan Patrick King, Lagrangeville, NY (US); Marc A. Gollub, Travis, TX (US); Louis Stermole, Jericho, VT (US); Stephen Glancy, Poughkeepsie, VA (US); Rochelle Barsz, Poughkeepsie, NY (US)

(21) Appl. No.: 19/179,140

(22) Filed: Apr. 15, 2025

(51) Int. Cl. G11C 29/56; G06F 11/34

(52) U.S. Cl. CPC G11C 29/56016; G06F 11/3466

(57) ABSTRACT

A method and/or system to determine execution of maintenance operations while concurrently running functional traffic. The maintenance operations can be performed based on monitoring environmental factors and also a time interval between consecutive maintenance operations. A reinforced learning model can be employed to predict optimal triggering of maintenance operations based on factors such as time, temperature, voltage, memory bandwidth, functional traffic, past maintenance results, parts characterization data, and/or others, to proactively trigger maintenance operations prior to a device error occurring, while not overly impacting system performance.

### BACKGROUND

The present application relates generally to computers and memory devices, and more particularly to concurrent device and/or processing component maintenance such as memory recalibration and/or maintenance facilitated by predictive or artificial intelligence model.

### BRIEF SUMMARY

The summary of the disclosure is given to aid understanding of a computer system and method of predictive model facilitated concurrent device maintenance, and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the computer system and/or their method of operation to achieve different effects.

In some embodiments, a computer-implemented method includes determining current data associated with a computer component, the computer component being associated with at least one processor. The computer-implemented method also includes, responsive to the current data meeting a criterion, triggering performing of a maintenance of the computer component. The computer-implemented method also includes, responsive to the current data not meeting the criterion, determining a time elapsed since a last previous maintenance of the computer component, and responsive to the time elapsed being greater than a maximum time count, triggering performing of a maintenance of the computer component. In some embodiments, the criterion and the maximum time count are dynamically updated based on outputs of an artificial intelligence (AI) model, where the AI model learns based on environmental and performance factors associated with at least the computer component.

In some embodiments, a computer-implemented method includes determining temperature of a memory device, the memory device coupled with at least a processor. The computer-implemented method also includes, responsive to the temperature exceeding a threshold, triggering performing of a calibration of the memory device. The computer-implemented method also includes, responsive to the temperature not exceeding the threshold, determining time elapsed since a previous calibration of the memory device, and responsive to the time elapsed being greater than a maximum time count, triggering performing of the calibration of the memory device. In some embodiments, the threshold and the maximum time count are dynamically updated based on outputs of an artificial intelligence (AI) model, where the AI model learns based on environmental and performance factors associated with the processor and the memory device.

In some embodiments, a system including a processor set, a set of one or more computer-readable storage media and program instructions, collectively stored in the set of one or more computer-readable storage media, for causing the processor set to perform the computer operations that include one or more methods described herein are also provided.

In some embodiments, a computer program product comprising a set of one or more computer-readable storage media, and program instructions, collectively stored in the set of one or more storage media, for causing a processor set to perform computer operations that perform one or more methods described herein also may be provided.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 shows an example of a computing environment, which can implement memory recalibration in some embodiments.

FIG. 2 is a flow diagram illustrating a method in some embodiments.

FIG. 3 is another flow diagram illustrating a method in some embodiments.

FIG. 4 is yet another flow diagram illustrating a method in some embodiments.

FIG. 5 illustrates a block diagram of one example of a memory buffer system configured in a unified memory buffer topology with a dedicated connection to an HSS interface in some embodiments.

FIG. 6 illustrates a process by which a memory buffer chip communicates with thermal sensors and obtains information from the thermal sensors in some embodiments.

FIGS. 7A-7B illustrate an example of a formatted log of memory alignment results obtained from performing a concurrent maintenance in some embodiments.

FIG. 8 illustrates a flow of a method that performs a device or a processing component maintenance based on one or more factors in some embodiments.

### DETAILED DESCRIPTION

In some embodiments, a computer-implemented method includes determining temperature of a memory device, the memory device coupled with at least a processor. The computer-implemented method also includes, responsive to the temperature exceeding a threshold, triggering performing of a calibration of the memory device. The computer-implemented method also includes, responsive to the temperature not exceeding the threshold, determining time elapsed since a previous calibration of the memory device, and responsive to the time elapsed being greater than a maximum time count, triggering performing of the calibration of the memory device. In some embodiments, the threshold and the maximum time count are dynamically updated based on outputs of an artificial intelligence (AI) model, where the AI model learns based on environmental and performance factors associated with the processor and the memory device.

In this way, the method checks both a temperature variable and a time elapsed since the time of the last maintenance. If at least one of those two checks is met, the method determines to take a calibration action. In this way, for example, even if the temperature does not exceed a given threshold, a calibration can take place at least once within a given maximum time count. In addition, the method can dynamically update one or more of the threshold, and the maximum time count, based on an AI model output. Such dynamic updates allow for optimizing memory calibration.

One or more of the following features can be separable or optional from each other.

In some embodiments, the triggering of the performing of the calibration of the memory device includes determining that a non-interruptible operation is in progress. The triggering of the performing of the calibration of the memory device also includes, responsive to determining that the non-interruptible operation is in progress, allowing the non-interruptible operation to finish running. The triggering of the performing of the calibration of the memory device also includes pausing an interruptible operation in progress. The triggering of the performing of the calibration of the memory device also includes calibrating the memory device. The triggering of the performing of the calibration of the memory device also includes logging results from the calibrating. The triggering of the performing of the calibration of the memory device also includes updating the AI model using the results. The triggering of the performing of the calibration of the memory device also includes resuming the interruptible operation. In this way, for example, one or more non-interruptible operations that are running are allowed to finish before a calibration takes place. Interruptible operations can be paused temporarily for the calibration to take place.

In some embodiments, the determining of the temperature and the determining of the time elapsed, are performed responsive to triggering of a timer. In this way, for example, calibration can be attempted at periodic intervals of time, e.g., based on timer triggers.

In some embodiments, the outputs of the AI model are used to dynamically update a trigger interval of the timer. In this way, the intervals of time used to trigger can also be optimized, e.g., automatically.

In some embodiments, the results from the calibrating are used to proactively identify suspect memory devices and pre-emptively deploy a mitigation action that minimizes workloads being exposed to a risk of memory corruption. In this way, potential computer system errors can be prevented.

In some embodiments, the determining that the temperature exceeds the threshold includes determining a temperature difference between the temperature and a temperature reading at a prior point in time, and determining that the temperature difference exceeds the threshold. In this way, thermal stability can be determined based on a temperature change from some prior point in time.

In some embodiments, the determining of that the temperature exceeds the threshold includes determining a temperature difference between the temperature and an average of a number of prior temperature readings, and determining that the temperature difference exceeds the threshold. In this way, thermal stability can be determined based on temperature change from some prior periods of time.

In some embodiments, the calibrating adjusts a timing of a data strobe (DQS) signal relative to data lines (DQ) of the memory device. For example, the calibrating performs DQS alignment.

In some embodiments, the environmental and the performance factors include at least time, temperature, voltage, memory bandwidth, functional traffic, past recalibration results, and parts characterization data associated with the memory device. For example, various different factors are considered by the AI model in its learning.

In some embodiments, the AI model is a reinforcement learning model, where a reward function of the reinforcement learning model considers at least a total number of calibration actions taken. The AI model learns its next action of whether or not to perform a calibration based on a reward received from its previous action.

In some embodiments, a computer-implemented method includes determining current data associated with a computer component, the computer component being associated with at least one processor. The computer-implemented method also includes, responsive to the current data meeting a criterion, triggering performing of a maintenance of the computer component. The computer-implemented method also includes, responsive to the current data not meeting the criterion, determining a time elapsed since a last previous maintenance of the computer component, and responsive to the time elapsed being greater than a maximum time count, triggering performing of a maintenance of the computer component. In some embodiments, the criterion and the maximum time count are dynamically updated based on outputs of an artificial intelligence (AI) model, where the AI model learns based on environmental and performance factors associated with at least the computer component.

The method checks both a current data associated with a computer component meeting a criterion, and a time elapsed since the time of the last maintenance. If at least one of those two checks is met, the method determines to take a maintenance action. In this way, for example, even if the current data associated with a computer component does not meet a given criterion, a maintenance can take place at least once within a given maximum time count. In addition, the method can dynamically update one or more of the criterion to meet, and the maximum time count, based on an AI model output. Such dynamic updates allow for optimizing computer component maintenance. For purposes of clarity and explanation only, this AI model is also referred to as a first AI model.

One or more of the following features can be separable or optional from each other.

In some embodiments, the triggering of the performing of the maintenance of the computer component includes determining that a non-interruptible operation is in progress. The triggering of the performing of the maintenance of the computer component also includes, responsive to determining that the non-interruptible operation is in progress, allowing the non-interruptible operation to finish running. The triggering of the performing of the maintenance of the computer component also includes pausing an interruptible operation in progress. The triggering of the performing of the maintenance of the computer component also includes performing a maintenance operation on the computer component. The triggering of the performing of the maintenance of the computer component also includes logging results from the calibrating. The triggering of the performing of the maintenance of the computer component also includes updating the AI model using the results. The triggering of the performing of the maintenance of the computer component also includes resuming the interruptible operation.

In this way, for example, one or more non-interruptible operations that are running are allowed to finish before a maintenance operation takes place. Interruptible operations can be paused temporarily for the maintenance operation to take place.

In some embodiments, the computer component includes a memory device, the current data includes voltage reading obtained from a voltage monitor associated with the at least one processor, the criterion includes whether a difference between the voltage reading and a past voltage reading exceeds a voltage threshold, and the maintenance operation includes calibrating the memory device. The method checks both the voltage difference exceeding the voltage threshold, and the time elapsed since the time of the last calibration operation on the memory device. If at least one of those two checks is met, the method determines to take the calibration action. In this way, for example, even if the voltage difference does not exceed the voltage threshold, a calibration can take place at least once within a given maximum time count. In addition, the method can dynamically update one or more of the voltage threshold, and the maximum time count, based on an AI model output. Such dynamic updates allow for optimizing performance of memory device calibrations.

In some embodiments, the computer component includes another AI model (also referred to as a second AI model for purposes of explanation only, different from the first AI model referred to above), the current data includes data associated with training of said another AI model, and the criterion includes whether a difference between the current data and prior used training data exceeds a differential threshold, and the maintenance operation includes retraining said another AI model. The method checks for both the differences in training data, and the time elapsed since the time of the last training of said another AI model. If at least one of those two checks is met, the method determines to take the retraining action. In this way, for example, even if the training data difference does not exceed the differential threshold, a retraining of said another AI model can take place at least once within a given maximum time count. In addition, the method can dynamically update one or more of the differential threshold, and the maximum time count, based on the AI model (the first AI model) output. Such dynamic updates allow for optimizing maintenance of said another AI model.

In some embodiments, the AI model is a reinforcement learning model, where a reward output by the AI model is used to dynamically update the criterion and the maximum time count. The AI model learns its next action of whether or not to perform a calibration based on a reward received from its previous action.

In some embodiments, the determining of the current data associated with the computer component, and the determining of the time elapsed since the last previous maintenance of the computer component are performed responsive to triggering of a timer. In this way, for example, maintenance can be attempted at intervals of time, e.g., based on timer triggers.

In some embodiments, the AI model is a reinforcement learning model, where a reward output by the AI model is used to dynamically update a trigger interval of the timer. In this way, the intervals of time used to trigger can also be optimized.

In some embodiments, a computer program product includes one or more computer-readable storage media. The computer program product also includes program instructions stored on the one or more storage media to perform the following operations. The operations include determining temperature of a memory device, the memory device coupled with at least a processor. The operations also include, responsive to the temperature exceeding a threshold, triggering performing of a calibration of the memory device. The operations also include, responsive to the temperature not exceeding the threshold, determining time elapsed since a previous calibration of the memory device, and responsive to the time elapsed being greater than a maximum time count, triggering performing of the calibration of the memory device. The threshold and the maximum time count are dynamically updated based on outputs of an artificial intelligence (AI) model, where the AI model learns based on environmental and performance factors associated with the processor and the memory device.

The operations check both a temperature variable and a time elapsed since the time of the last maintenance. If at least one of those two checks is met, the operations determine to take a calibration action. In this way, for example, even if the temperature does not exceed a given threshold, a calibration can take place at least once within a given maximum time count. In addition, the operations can dynamically update one or more of the threshold, and the maximum time count, based on an AI model output. Such dynamic updates allow for optimizing memory calibration.

One or more of the following features can be separable or optional from each other.

In some embodiments, the operation of the triggering of the performing of the calibration of the memory device includes determining that a non-interruptible operation is in progress. The operation of the triggering of the performing of the calibration of the memory device also includes, responsive to determining that the non-interruptible operation is in progress, allowing the non-interruptible operation to finish running. The operation of the triggering of the performing of the calibration of the memory device also includes pausing an interruptible operation in progress. The operation of the triggering of the performing of the calibration of the memory device also includes calibrating the memory device. The operation of the triggering of the performing of the calibration of the memory device also includes logging results from the calibrating. The operation of the triggering of the performing of the calibration of the memory device also includes updating the AI model using the results. The operation of the triggering of the performing of the calibration of the memory device also includes resuming the interruptible operation. In this way, for example, one or more non-interruptible operations that are running are allowed to finish before a calibration takes place. Interruptible operations can be paused temporarily for the calibration to take place.

In some embodiments, the operations of the determining of the temperature and the determining of the time elapsed, are performed responsive to triggering of a timer. In this way, maintenance can be attempted at intervals of time, e.g., based on timer triggers.

In some embodiments, the operation of the triggering of the timer is configured based on the outputs of the AI model. Maintenance can be attempted at intervals of time, e.g., based on timer triggers, which can be optimized, and dynamically and/or automatically updated.

In some embodiments, a computer program product includes one or more computer-readable storage media. The computer program product also includes program instructions stored on the one or more storage media to perform the following operations. The operations include determining current data associated with a computer component, the computer component being associated with at least one processor. The operations also include, responsive to the current data meeting a criterion, triggering performing of a maintenance of the computer component. The operations also include, responsive to the current data not meeting the criterion, determining a time elapsed since a last previous maintenance of the computer component, and responsive to the time elapsed being greater than a maximum time count. triggering performing of a maintenance of the computer component. The criterion and the maximum time count are dynamically updated based on outputs of an artificial intelligence (AI) model, where the AI model learns based on environmental and performance factors associated with at least the computer component.

The operations check both a current data associated with a computer component meeting a criterion, and a time elapsed since the time of the last maintenance. If at least one of those two checks is met, the operations determine to take a maintenance action. In this way, for example, even if the current data associated with a computer component does not meet a given criterion, a maintenance can take place at least once within a given maximum time count. In addition, the operations can dynamically update one or more of the criterion to meet, and the maximum time count, based on an AI model output. Such dynamic updates allow for optimizing computer component maintenance. For purposes of clarity and explanation only, this AI model is also referred to as a first AI model.

One or more of the following features can be separable or optional from each other.

In some embodiment, the operation of the triggering of the performing of the maintenance of the computer component includes determining that a non-interruptible operation is in progress. The operation of the triggering of the performing of the maintenance of the computer component also includes, responsive to determining that the non-interruptible operation is in progress, allowing the non-interruptible operation to finish running. The operation of the triggering of the performing of the maintenance of the computer component also includes pausing an interruptible operation in progress. The operation of the triggering of the performing of the maintenance of the computer component also includes performing a maintenance operation on the computer component. The operation of the triggering of the performing of the maintenance of the computer component also includes logging results from the calibrating. The operation of the triggering of the performing of the maintenance of the computer component also includes updating the AI model using the results. The operation of the triggering of the performing of the maintenance of the computer component also includes resuming the interruptible operation.

For example, one or more non-interruptible operations that are running are allowed to finish before a maintenance operation takes place. Interruptible operations can be paused temporarily for the maintenance operation to take place.

In some embodiments, the operations of the determining of the criterion and the determining of the time elapsed, are performed responsive to triggering of a timer, and where the AI model is a reinforcement learning model, where a reward output by the AI model is used to dynamically update a triggering interval of the timer. In this way, maintenance can be attempted at intervals of time, e.g., based on timer triggers, which can be dynamically and/or automatically updated.

In some embodiments, a computer system includes a processor set. The computer system also includes a set of one or more computer-readable storage media. The computer system also includes program instructions, collectively stored in the set of one or more computer-readable storage media, for causing the processor set to perform the following computer operations. The computer operations include determining current data associated with a computer component, the computer component being associated with at least one processor. The computer operations also include, responsive to the current data meeting a criterion, triggering performing of a maintenance of the computer component. The computer operations also include, responsive to the current data not meeting the criterion, determining a time elapsed since a last previous maintenance of the computer component, and responsive to the time elapsed being greater than a maximum time count, triggering performing of a maintenance of the computer component. The criterion and the maximum time count are dynamically updated based on outputs of an artificial intelligence (AI) model, where the AI model learns based on environmental and performance factors associated with at least the computer component.

The system checks both a current data associated with a computer component meeting a criterion, and a time elapsed since the time of the last maintenance. If at least one of those two checks is met, the system determines to take a maintenance action. In this way, for example, even if the current data associated with a computer component does not meet a given criterion, a maintenance can take place at least once within a given maximum time count. In addition, the system can dynamically update one or more of the criterion to meet, and the maximum time count, based on an AI model output. Such dynamic updates allow for optimizing computer component maintenance. For purposes of clarity and explanation only, this AI model is also referred to as a first AI model.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as concurrent device maintenance code 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

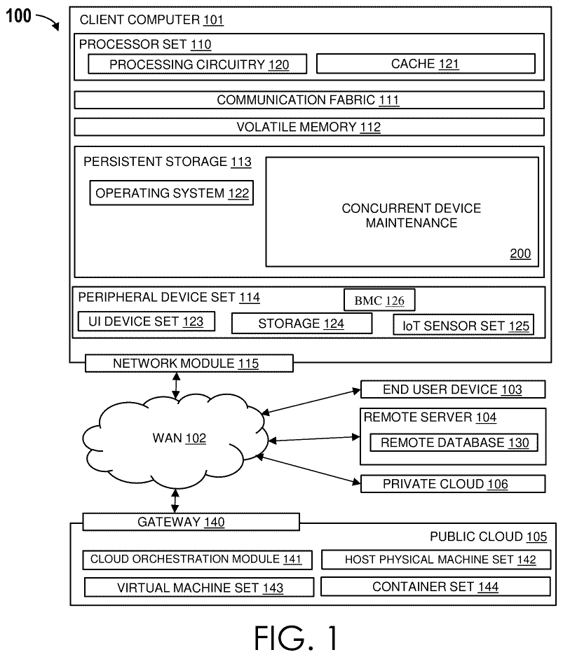

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

In some embodiments, systems, methods and/or techniques (also generally referred to as a technique or techniques) are provided for concurrent memory calibration operation. Memory calibration is also referred to as memory maintenance. Memory calibration (also referred in short as calibration) generally aligns data strobe signals or clock signals with data lines to accurately read or write data. In concurrent memory maintenance and/or calibration, one or more calibration operations take place while a computer system or an electronic device is running, for example, while operating system and/or user application operations or traffic are in progress. In some embodiments, systems, methods and/or techniques provide for performing a proactive concurrent memory maintenance and/or calibration operation in non-disruptive manner, e.g., without detracting from overall system performance. For example, in some embodiments, the frequency of performing a concurrent memory calibration operation is determined such that the maintenance is performed before an occurrence of an actual error, but still at a rate which does slow down or negatively affect the system performance.

Evolving memory technologies are trending towards more concurrent maintenance activities such as on-die error correction code (ECC), periodic calibrations, DQS interval offset. An example of a memory calibration operation is a DQS interval offset. DQS refers to data strobe, a signal or clock signal used in memory read and write, e.g., a strobe pin used in double data rate (DDR) memory to latch data. DDR is a type of memory technology used in computers and other electronic devices.

DQS interval offset is a feature that allows a calibration routine to perform periodic DQS alignment during functional traffic. DQS interval offset provides dynamic random access memory (DRAM) vendors more latitude in their clock tree and data routing by relying on the calibration to recover lost margin due to voltage or temperature variation.

In some embodiments, techniques disclosed herein provide an approach to continuously adapt the system to future memory changes, e.g., new dies, faster DDR frequencies, extended DDR life cycle, new maintenance and reliability, availability, and serviceability (RAS) features in DDR versions.

Periodic maintenance routines can interrupt functional traffic. In some embodiments, techniques disclosed herein initiate a maintenance and/or calibration operation or routine in a way that co-exists with other memory related activity which needs to be performed in a timely manner, and performs such maintenance and/or calibration operation in a way that is non-disruptive to mainline traffic or detracts from overall system performance, and also at the same time allows for the required amount of proactive maintenance that can reduce or eliminate RAS risk exposures.

In some embodiments, the techniques disclosed herein consider one or more of various environment factors as a criterion or criteria for performing a calibration operation. For example, the calibration margin is a function of environmental factors such as system temperature, workload, operating frequency and parts variation. The techniques disclosed herein consider the following challenges in deciding or determining an optimal time for a calibration operation. For instance, triggering the calibration using a fixed time interval alone may not align with changing environmental factors; Using a temperature or thermal factor to dynamically trigger the calibration interval is an improvement but if used as a stand-alone method may not be sufficiently error-free; For example, depending on how the temperature is sampled, the temperature may change at the same pace as samples occur causing the temperature to appear relatively consistent when in fact there are significant fluctuations occurring outside the sample windows. Monitoring the DQS drift to autonomously trigger the calibration is a reactive approach which can conflict with other activities; Some interface frequencies may require even more advanced triggering methods. For example, newer memory or DDR interfaces may operate at 19.2 gigabits per second.

As described above, an example of a maintenance or calibration operation is DQS alignment. DQS alignment, as related to DDR memory, generally can be considered as an operation or process of aligning the timing of the DQS signal with the data (DQ) signal, so that the data is sampled at the correct point within the clock cycle, e.g., in memory devices such as DDR RAMs. For example, the edges of the DQS signal are aligned to the center of the DQ data window to accurately capture the data bits. For instance, based on detecting how much a data strobe has drifted from its associated data bits since the initial calibration, e.g., at a startup of a device, the timing of the DQS signal with data (DQ) signal can be re-aligned periodically.

In some embodiments, methods described herein perform memory calibration on a device (e.g., a computer or another device) having at least a processor (e.g., computer processor such as a central processing unit (CPU), another type of a processor) and memory (e.g., DRAMs).

For instance, a DRAM can be connected to a computer processor through a memory controller, which sits on a motherboard and communicates with the processor using a dedicated bus, allowing the CPU to access data stored in the DRAM quickly and directly. For example, the processor may send requests to the memory controller, which then accesses the relevant data in the DRAM modules plugged into the motherboard's DIMM slots. A CPU connects to a memory controller that connects to DRAM. In some embodiments, a memory controller is part of the processor or CPU. In DDR (Double Data Rate) memory, DQS calibration refers to the process of adjusting the timing of the data strobe (DQS) signal relative to the data lines (DQ) to ensure accurate data capture by aligning the DQS signal with the data line for accurate data reading and writing. For example, DQ lines, or data lines, are the bidirectional lines that transfer data on DDR (Double Data Rate) memory.

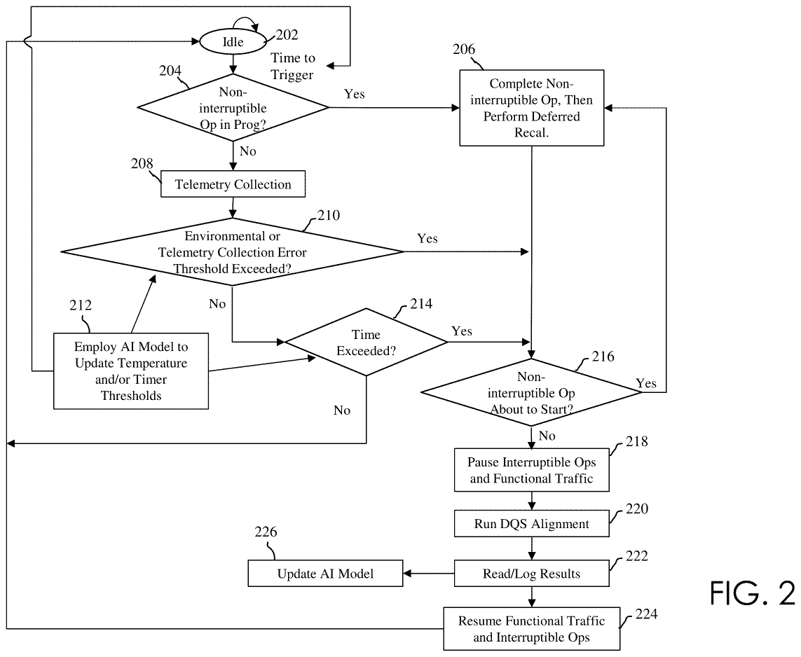

FIG. 2 is a flow diagram illustrating a method in some embodiments. The method provides for memory recalibration, and can be run or performed by one or more computer or hardware processors, e.g., a memory controller, a memory buffer chip, and/or another. In this embodiment, the method employs an artificial intelligence (AI) model to update temperature threshold and/or timer threshold, which are used to determine whether memory recalibration should be performed. For instance, the method employs an AI model that dynamically can determine the predetermined threshold that is compared with the temperature delta associated with memory devices and/or the maximum amount of time that is compared with the time period since the last calibration. An example of the AI model is a reinforcement learning model.

For instance, the method employs a reinforcement learning model to dynamically trigger the update based on real time learning. In some embodiments, inputs for training such a reinforcement learning model may include, but are not limited to: real time thermal readings; real time bandwidth calculations; cumulative calibration count; a number of (e.g., 24) deep logs of prior alignment activities (prior calibration operations), such as temperature or time based trigger, number of executions or operations performed in device since last recalibration, alignment (e.g., DQS) correction information per DRAM; characterization database of alignment (e.g., DQS alignment) results with associated operating conditions and pedigree information for a broad sampling of parts (e.g. voltage, frequency, temperature, vendor, die revision, size, and/or others). For instance, DRAMs from different vendors can be characterized based on how those memory devices behave under various environmental conditions, voltage, temperature, frequency, and/or others. The amount of margin those devices have and how they operate under those different conditions can also be fed into the reinforcement learning model. Depending on the types of memory devices (e.g., DIMMs, DRAMs) plugged into a specific computer system or device, the reinforcement learning model may produce different outcomes. For example, the reinforcement learning model may produce different trigger points (e.g., temperature delta threshold, timer threshold) for different computer systems or devices. For example, for a computer system, the maximum amount of time between calibrations can be longer than another computer system, for instance, because that computer system may have a more stable environment and/or is running constant and predictable workloads, and thus can tolerate a longer time period between calibrations.

For example, performance metrics such as bandwidth on memory channels, e.g., how much the memory channels are being utilized at any point in time and also the patterns of bandwidth can be utilized by an AI model in determining trigger points.

At 202, a processing idles, waiting for a timer to trigger. This processing can be in a form of a thread or a process that is running in a background, for example, as a daemon process, or another process on a computer of another processing device. There can be a timer that triggers periodically, e.g., every interval or period. For example, at every interval of time, a timer triggers, which wakes up a routine, e.g., a firmware routine, e.g., for performing memory calibration such as DQS alignment. This interval can be configurable, e.g., predefined, and also may be dynamically changeable in some embodiments as will be described in more detail below.

At 204, the routine determines whether a non-interruptible operation is running or in progress in a computer system or device. Examples of non-interruptible operations include priority operations such as a recovery operation, a repair operation, or another type of operation that may be critical for proper running or maintenance of the computer system or device. In some embodiments, a non-interruptible operation may be running on a processor of the computer system, and/or a memory buffer chip, and/or elsewhere associated with the computer system and/or device. Non-interruptible operations should not be interrupted while they are running.

At 206, if a non-interruptible operation is in progress, the routine waits for the non-interruptible operation to complete. The routine resumes calibration or recalibration operation after the non-interruptible operation completes, e.g., proceeds to 216.

At 208, if the routine determines there are no non-interruptible operations in progress, the routine performs a telemetry collection, which includes reading various sensors or monitors to obtain the current environmental elements that apply to the calibration under consideration. For example, in the case of DQS interval offset (DQS alignment), the routine reads the current temperature of the dual in-line memory modules (DIMMs). The routine obtains readings from sensors such as temperature sensors associated with one or more memory devices. By way of example, the thermal sensors that participate in the process can be a combination of discrete temperature sensors on the memory DIMMs and embedded thermal sensors in the memory buffer chips. Other types of calibration or maintenance may rely more heavily on different environmental elements such as voltage, current, power, frequency, humidity, pressure and/or the like. Depending on the environmental factor that is used for the calibration operation, the routine at 208 employs the associated data collection, e.g., collects appropriate environment data for the type of calibration operation.

By way of example, telemetry data may include, but are not limited to, cumulative count of recalibrations; log entry for each of last predefined number (e.g., 24) of recalibrations, which may include, but are not limited to, trigger (temperature or time-based), count of tracking executions since the occurrence of a previous recalibration (calibration), and DIMM temperature; Correction information of a predefined number (e.g., 3) of most-affected DRAMs or memories, which may include but are not limited to, correction amount, rank, DRAM index, and chip temperature. In addition, performance information from performance counters or registers can be collected. Examples of performance information that are collected may include, but are not limited to, bandwidth, utilization or latency of memory channel operations, controls for thresholds, wrapping and sampling rate, data from counters that hold sum, maximum and average values of performance, information from latency and histogram counters, operational filters, counts of individual events, latency values over programmable ranges or average latency over a time span.

In some embodiments this performance information is periodically collected by hardware facilities and stored in firmware accessible registers. The AI model can access the bandwidth counters as input to the reinforcement learning model. The AI model may access and monitor bandwidth, utilization and histogram counters over periods of time to learn about workload patterns and use that information to improve the accuracy of the results if the AI model knows (for example) that certain utilization patterns are likely to occur at certain times. For instance, a transaction processing system may be more heavily loaded during normal business hours and lightly loaded overnight. As another example, a computer system involved in retail may regularly experience spikes around the holiday season or high shopping periods. The AI model may further use this information to adjust timers based on time of day or calendar periods.

At 210, the routine compares the environmental information (temperature, voltage, and/or other environmental information) collected at 208 to one or more trigger thresholds. For example, delta values of the current and prior (or historical average) environmental information can be compared with one or more trigger thresholds (also referred to as environmental thresholds). If one or more of the delta values exceed one or more corresponding trigger thresholds, the routine proceeds to 216. If the delta values do not exceed corresponding trigger thresholds, the routine proceeds to 214. These trigger thresholds are determined by an AI model, e.g., the reinforcement learning model, and may be dynamically adjusted by the reinforcement learning model as the various parameters that influence the reinforcement learning model changes during a running of a computer system or device as shown at 212. For example, at 212, an AI model such as the reinforcement learning model may determine that the current run time parameters are such that the temperature threshold could be increased (thereby allowing more thermal deviation without the need to trigger a concurrent operation) but conversely a voltage threshold needs to decrease (thereby demanding a tighter tolerance on a voltage rail to prevent a recalibration). In some embodiments, the AI model runs concurrently while the computer system is running. The AI model is continuously updating and producing recommendations on adjusting the threshold and/or trigger points.

In some embodiments, under normal circumstances these environmental thresholds serve as the primary factor in deciding whether to trigger a calibration event. In some embodiments, since the environmental thresholds rely on various sensors or monitors, the possibility exists that a sensor or monitor may fail, or an error may occur while performing this telemetry collection. In this situation, in some embodiments, the routine employs a programmable telemetry collection error threshold (e.g., threshold error count) where if the error threshold is exceeded (e.g., the number of telemetry collection errors exceeds the telemetry collection error threshold), the routine immediately triggers a calibration event. As shown at 210, the routine proceeds to 216. If the error threshold is not exceeded, the routine proceeds to 214. This allows for various systems and infrastructures to determine how much of an error rate is to be tolerated before assuming that the environmental conditions may have exceeded any of the environmental thresholds that would normally trigger a calibration. In some embodiments, the method also permits the resetting of the telemetry collection error counts upon the triggering of a calibration due to a telemetry collection error.

If there are no telemetry collection (sensor or monitor) errors and none of the environmental thresholds being considered have been exceeded, then the routine at 214 uses a governor timer so that at least one calibration event is performed at a prescribed interval. This protects against pathological situations where environmental parameters could take on a “harmonic like” behavior resulting in the telemetry collection erroneously indicating that the environment is more stable than it really is, and thus not performing a calibration. The governor timer guarantees that a calibration will be performed at some point. This is another programmable element whose threshold value is determined by the reinforcement learning model, e.g., shown at 212, which dynamically adjusts this timer threshold as the system environmental parameters change during run time. For example, the AI model may also update the maximum amount of time between calibrations. In some embodiments, the method or the routine also resets the timer (governor timer) in situations where a calibration is forced due to environmental threshold or telemetry collection error thresholds being exceeded. In some embodiments, the outputs of the AI model are also used to dynamically update a trigger interval of the timer, used at 202 for waking up an idling routine. Thus, for example, any one or more of the environmental threshold used for comparing at 210, the maximum time count used at 214, and timer trigger interval or period used at 202, can be adjusted based on or by the AI model.

At 216, the routine again checks whether a non-interruptible operation is about to start. For example, because such operations may be driven based on interrupts, the routine rechecks whether another interruptible operation is about start before proceeding with calibration. If the routine determines that a non-interruptible operation is about to start, the routine proceeds to 206, waiting for that non-interruptible operation to finish. If the routine determines that no non-interruptible operation is about to start, the routine proceeds to 218.

At 218, the routine pauses one or more interruptible operations in progress in the computer system or device. For example, a memory controller operation may save the current state of an interruptible operation (such as background scrubbing of memory), stop that operation, then restore the saved state when the interruptible operation is to be resumed.

At 220, calibration is performed. For example, the routine runs DQS alignment, which adjusts a timing of a data strobe (DQS) signal relative to data lines (DQ) of the memory. Briefly, a DQS alignment process is technically known as DQS Interval Offset in the Joint Electron Device Engineering Council (JEDEC) standard. It includes performing the following steps: 1. Send a Multi-Purpose Command (MPC) to initiate the DQS Interval Oscillator; 2. Either wait a pre-determined amount of calibration time—or—issue an MPC to manually stop the calibration after a desired amount of time; 3. Issue two Mode Register Read (MRR) operations to extract the calibration results from the DRAM devices; 4. Perform the required propagation updates to the DQS transceiver circuitry on the host chip based on the information provided by the results obtained from the two MRR operations.

At 222, the routine records or logs data associated with the calibration such as data results. Data that is logged can include cumulative count of various data from recalibrations. Examples include, but are not limited to, log entry for each of last X number of recalibrations, where X can be configurable. For example, log entry for each of last 24 recalibrations can be logged or recorded, which can include the type of trigger (e.g., temperature or time-based), count of tracking executions since the occurrence of the previous recalibration, and DIMM temperature. More examples of data that is logged can include correction information for all of the DRAM devices or a subset of DRAMs, (e.g., 3 most-affected DRAMs), such as correction amount, rank, DRAM index, and chip temperature. The results are also used to update the learning of the AI model at 226. For example, log information or results from alignment operations (e.g., every DQS alignment performed) can be used by the AI model in addition to monitored environmental and other aspects of a computer system or device. The AI model may use all those different types of information to learn and make decisions.

In some embodiments, recalibration (calibration) results are incorporated into runtime diagnostics to proactively identify suspect memory devices before actual memory errors occur. For example, the logged results track the drift at a device level, and therefore, the recalibration results can be used to predict which DRAMs have drifted far enough such that they are in imminent risk of providing corrupted data over the DDR interface. Depending on how many DRAMs are at risk, the following known techniques can be pre-emptively deployed: Deploying ECC chip marks (also known as ECC chip kill correction); Deploying spare DRAMs; If more DRAMs are at risk than can be handled with chip marks and spare DRAMs, customer workloads can be moved to another working memory in a subject computer system, such that those workloads are no longer at risk of imminent uncorrectable memory corruption. For example, the results from the calibrating are used to proactively identify suspect memory devices and pre-emptively deploy a mitigation action that minimizes workloads being exposed to a risk of memory corruption.

At 224, the routine resumes the interruptible operations that were paused at 218, e.g., resumes the applications that were running in the computer system or device. For instance, the saved state of the interruptible operations are restored. The routine then proceeds to idling at 202, e.g., and wait for the next trigger.

In some embodiments, a reinforcement learning model may use the following as its state: temperature or temperature difference between current and previous temperature at a given point in time, amount of time exceeded since last alignment, DQS offset from last update (e.g., amount of alignment offset), voltage variation (e.g., occurring on voltage rails that influence the memory device), current bandwidth (e.g., traffic and traffic pattern), system frequency (e.g., the higher the system frequency, more calibrations may need to be performed), DRAM characteristics. An action of the reinforcement learning model whether to perform an alignment, e.g., DQS Alignment, for example, Yes or No. A reward component or formula for the reinforcement learning model can consider the factors such as temperature and time between alignments. The reward formula can be further enhanced to include aspects such as performance metrics (e.g., memory bandwidth), voltage and part specific (e.g., memory device specific) characterization data.

An example reward (R) component or formula of the reinforcement learning model may include the following: R=total_triggers( )+abs (prev_offset)*10+BW+total_levels( )+percent_V( ) where BW refers to bandwidth, prev_offset is previous DQS offset results (e.g., how much drift has occurred), total_triggers( ) is the sum of all attempted alignments based on timer and/or threshold being exceeded, total_levels( ) is the sum of levels assigned to the system frequency as well as specific DIMM characterization, and percent_V( ) is percent deviation from nominal voltage. A different reward formula can be used. Another example of the reward formula can be: total_triggers ( )+abs (prev_offset)*10+BW. By way of yet another example, R=−ΔT−0.1·Δt−f, where f: DQS offset from previous update, T: Temperature, t: Time.

In some embodiments, total triggers used in a reward formula refer to a count of time and an environment variable such as temperature exceeding respective thresholds since the previous alignment. For instance, total triggers refer to the number of times the calibration is attempted or triggered, e.g., based on one or more environmental factors (e.g., temperature) exceeding a corresponding threshold, and/or a timer exceeding a corresponding threshold. This total triggers value relates to the number of “attempts” in Time to Trigger 202. By way of example, consider that a trigger interval (Time to Trigger) is set to 1 second and the “governor timer” or the maximum time count (used at 214) is set to 1 minute. At time 0, a process begins. At 1 second, the process “wakes up” (e.g., at 202), checks the temperatures, determines that there is no temperature change, then checks the governor timer (e.g., at 214), determines that 1 minute has not elapsed, so the process goes back to sleep or idling. Time advances. At 2 seconds, the process wakes up (e.g., at 202) and repeats the same process. Again, the process determines that there are no changes in temperature, therefore, the process goes back to sleep. This procedure continues every second. Now, consider that the process gets to the 59th second, wakes up, checks for change in temperature, and determines that there is no change, and goes back to sleep. At the 60th second, the process wakes up, checks the temperature, and determines that there is no temperature change, checks the maximum time count or governor timer (e.g., at 214) and determines that the time exceeded the maximum time count, and therefore, the process proceeds to perform a calibration. When that data gets logged, the total triggers will be 60 because there were 60 attempts until the condition to execute an actual calibration was met. By way of another example, consider that the process instead detected a large temperature delta at the 29th second, and thus kicked off an alignment, then that log result would show 29 total triggers.

Total levels used in a reward formula refer to the sum of levels assigned for system customization. Levels are weights assigned to various parameters. For example, a system having 3200 megabits per second (Mbps) frequency or speed can be classified as being level 0, a system having 4000 megabits per second (Mbps) frequency or speed can be classified as being level 1, and a system having 4800 megabits per second (Mbps) frequency or speed can be classified as being level 2. As another example, DIMM characterization levels can be classified into levels as shown in Table 1. By way of example, higher frequency devices may get a higher level (or weight) since higher frequency devices may need more frequent calibrations.

TABLE 1

| DRAM | | | | Min Right | |
|---|---|---|---|---|---|
| Vendor | Device Type | Size | Die Rev | Eye Margin | Level |
| Vendor X | 32 Gb | x4 | 4000BN | 50 | 0 |
| Vendor Y | 48 Gb | x4 | 4800C | 10 | 4 |
| Vendor Z | 64 Gb | x4 | 6400F | 33 | 3 |

Different parts or components of a computer system, which may affect the trigger points and reinforcement learning model decisions, can also be tracked and characterized.

Percent V used in a reward formula refers to the sum of percentage (%) deviation of voltage rails from nominal voltage.

A higher reward provides greater incentive to the reinforcement learning model to perform an alignment (an action). For example, higher reward results in alignment (memory alignment such as DQS alignment) being performed at an increased rate. Given the state, the reward is computed, and given the reward, the reinforcement learning model decides whether to perform or take an action. Taking an action further may change the state, which triggers the reward being recomputed. Based on the reward, the reinforcement learning model makes another decision on action. In this way, the reinforcement learning model can project an optimal number of calibrations to be performed.

By way of example, at a given state, the reinforcement learning model selects an action using an epsilon-greedy Q-learning approach to balance exploitation and exploration. The action is a binary decision, determining if an alignment is necessary at this time. The state, action, reward, and previous state are stored in the model's memory such that the model's decision-making is optimized when revisiting a similar state. Taking an action further may change the state, which triggers another action, reward calculation, and insertion into the model's memory. The frequency of calibration is determined based on the average of the time between last N number of attempts to perform an alignment, where N is an integer, which may be configurable or predefined. For example, the frequency of calibration is determined as the average of the time between the last 100 attempts to perform an alignment. In this way, the reinforcement learning model can project an optimal frequency of calibrations to be performed.

In some embodiments, using a reinforcement learning model reduces the number of calibration updates, by the reinforcement learning model continuously monitoring prior calibration results along with current thermal and performance metrics. Such operational results can be used to dynamically update the trigger frequency based on environment changes during system run time.

For example, considering the total number of triggers, one may adjust trigger points (e.g., thresholds). If the total number of triggers is high, it means that the thresholds are being exceeded. In such instances, one or more thresholds may be adjusted, e.g., increased. For example, if the temperature threshold is set of 5 degrees Celsius, it may be changed to 10 degrees Celsius such that the threshold is not exceeded. On the other hand, if the total number triggers is low, it means that the thresholds are not being exceeded. In that situation, the threshold may be decreased. For example, continuing with the temperature threshold, it may be changed to 3 degrees Celsius. By way of another example, if there are large drift offsets, the temperature threshold may be decreased to increase the number of triggers. Thus, in some embodiments, the thresholds are adjusted as a result of the AI model output. The AI model (in turn) uses the total triggers, among other information or data, as one of its inputs. For instance, the total triggers is one of the components feeding into the reward based formula. The AI model provides a guidance for setting the thresholds such that a minimum number of calibrations is performed for preventing occurrence of a memory error.

In some embodiments, the AI model interfacing with a firmware of a controller may perform the adjusting of the thresholds, for example, based on the AI model's outputs. An example of such a controller is a Baseboard Management Controller (BMC). BMCs, also referred to as Service Elements (SE), are dedicated or specialized processors that manage and maintain a main computer system. A BMC 126 or like specialized processor can be included in the peripheral device set 114 shown in FIG. 1. These controllers or BMCs are loaded with firmware and applications that run continuously, monitoring the main computer system and intervening to perform required maintenance tasks. Facilities can also be embedded in the processor and memory chips to provide hardware assists to these SE and BMC firmware applications.

In some embodiments, the thresholds, timers and triggers are programmed via “attributes” in the firmware procedures that are controlled by these SE and BMC facilities. These “attributes” are programmable settings, e.g., attributes, variables, or values in a hardware facility (e.g., register or storage element) that is accessible via an application programming interface (API) or programming interface. Via such API or programming interface, the AI model can update the attributes, e.g., program the settings. In some embodiments, the AI model may automatically adjust the attributes based on its output, e.g., adjust a temperature threshold by an increment.

The AI model can be implemented in different ways. In some embodiments, the AI model may be implemented entirely as a firmware or a software routine. The AI model implemented as such firmware or software routing may use one or more APIs to interface with a BMC to obtain the various telemetry and sensor inputs, and adjust the thresholds, timers, and/or triggers based on its results or output. In some other embodiments, the AI model may be permanently embedded within hardware AI engines such as the AI unit on a processor or AI cards. In yet in some other embodiments, the AI model may be implemented as a combination of software and firmware routines that are loaded and accelerated with dedicated AI hardware such as AI engines.

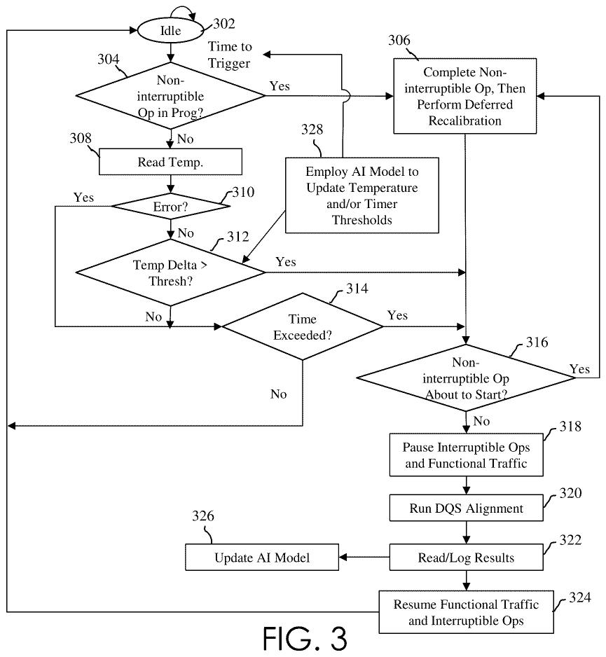

FIG. 3 is another flow diagram illustrating a method in some embodiments. The method provides for memory calibration or recalibration, and can be run or performed by one or more computer or hardware processors, e.g., a memory controller, a memory buffer chip, and/or another. An example of a hardware processor is a memory controller. For example, a memory controller may perform DQS alignment, which aligns the Data Strobe (DQS) signal with the Data (DQ) signals on a DDR memory interface, to provide for accurate data sampling and reliable data transfer between a computer processor and memory modules. The method in this embodiment employs an AI model such as a reinforcement learning model described above to dynamically trigger the calibration based on real time learning.

The method also employs an AI model such as a reinforcement learning model described above to dynamically update a timer used to wakes up a routine for performing memory calibration, and also to dynamically update a temperature threshold, which are used to determine whether memory recalibration should be performed. As described above, by way of example, the AI model may interface with a BMC or like specialized processor, in updating various thresholds and/or triggers.

At 302, a processing idles, waiting for a timer to trigger. This processing can be in a form of a thread or a process that is running in a background, for example, as a daemon process, or another process on a computer of another processing device. The time intervals to trigger this timer (e.g., when to trigger the timer) are controlled based on the AI model as shown at 328, for example, a reinforcement learning model, which learns the optimal times to trigger this timer. For instance, based on the AI model's output, the time intervals are dynamically updated. The timer triggers at intervals of time specified according to the AI model's output. Triggering of the timer wakes up a routine, e.g., a firmware routine for performing memory calibration such as DQS alignment.

At 304, the routine determines whether a non-interruptible operation is running or in progress in a computer system or device. Examples of non-interruptible operations include priority operations such as a recovery operation, a repair operation, or another type of operation that may be critical for proper running or maintenance of the computer system or device. In some embodiments, a non-interruptible operation may be running on a processor of the computer system, and/or a memory buffer chip, and/or elsewhere associated with the computer system and/or device.

At 306, if a non-interruptible operation is in progress, the routine waits for the non-interruptible operation to complete. The routine resumes calibration or recalibration operation after the non-interruptible operation completes, e.g., proceeds to 316.

At 308, if no non-interruptible operation is in progress, the routine reads the temperature of the computer system or device. The temperature readings, for example, can be obtained from various sensors that measure temperature of a computer system or device. The routine, reads sensors, such as temperature sensors, associated with one or more memory devices. By way of example, the thermal sensors that participate in the process can be a combination of discrete temperature sensors on the memory DIMMs and embedded thermal sensors in the memory buffer chips.

At 310, the routine determines whether there is an error in reading the temperature. If an error is encountered in reading the temperature, the routine proceeds to another check at 314. An error may be detected if a temperature sensor is not working properly, or a function that is collecting temperature data is not functioning properly, or another improper functioning of components involved in obtaining temperature data. Since in such situations, there is no valid temperature data, the routine skips the determining of whether to perform a calibration based on a temperature reading.

At 312, if no error is encountered in reading the temperature, the temperature that is read (current temperature) is compared to a past temperature data, e.g., historic temperature (e.g., last temperature reading, or an average of a number of prior temperature readings, where the number can be predefined). The difference (referred to as temperature delta) between the current temperature and the historic temperature is compared to a threshold. The threshold is a dynamic value that is updated based on an AI model's output. For instance, the AI model can be a reinforcement learning model, described above, which continuously learns the optimal threshold values based on the state of an environment, taking an action and associated reward. In some embodiments, optimal thresholds can be determined through computing a value, referred to as P for simplicity of explanation, for instance, optimal temperature threshold and trigger times can be found through computing value P. P represents a fraction of the current value to use as the adjustment for a new value. When the AI model chooses action to perform a maintenance operation, the AI model or a controller computes P as, P=1/(log (1+R)), where R is the value of the computed reward. For example, consider a temperature threshold. Consider also an initial threshold of 5 degrees Celsius (C). The AI model computes a reward (R), e.g., of 5. This R value, 5, can be plugged into the P formula, resulting in P=1.28. This is the fraction (or percentage) of the current value to use for the adjustment. In some embodiments, a program (e.g., firmware or software) running on a computer system can perform this updating. For example, such a program multiplies P by the current value (hence 1.28×5 degrees C.) and gets a new threshold value of 6.4 degrees C. Hence, at 812, the routine compares the temperature delta against 6.4 (not 5), e.g., in the case the environmental factor being used is temperature. Consider that the process has run for a while and the AI model produces a new R of 60. That new R value in turn results in a different value of P, i.e., P=0.56 (when 60 is used in the above P formula). Consequently, the program adjusts the current temperature threshold by 0.56 (6.4×0.56) to get a new temperature threshold of 3.58. In some embodiments, as illustrated by the above example, such a formulation (e.g., P formulation) can adjust the threshold and converge on a stable value, for example, an optimal value. In some embodiments, a program (e.g., firmware or software) running on a computer system can perform this updating or adjusting of the threshold. In some other embodiments, an administrator or the like can manually update the threshold based on the output of the AI model. Similar P formulation concept can be applied to adjust the time to trigger at 302 and also the maximum time count at 314. Other methodologies can also be used in determining the adjustment values.

If the temperature delta exceeds the threshold, the routine proceeds to calibration, e.g., proceeds to 316. If the temperature delta does not exceed the threshold, the routing proceeds to another test or check at 314.

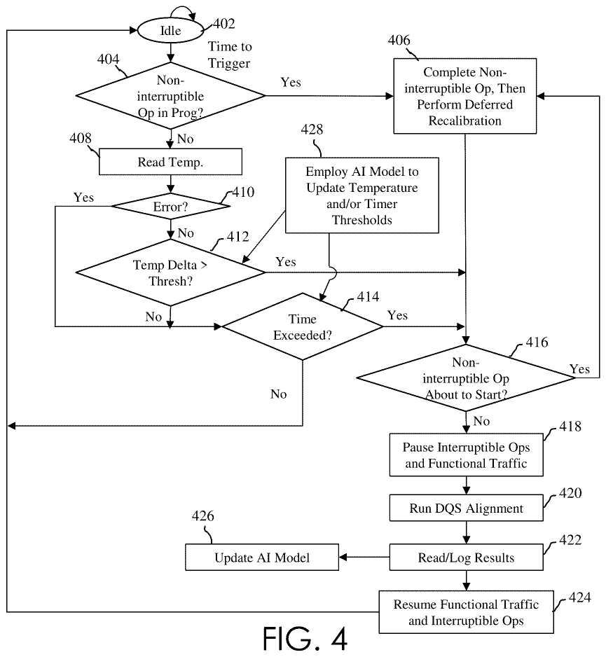

At 314, the routine determines whether a time period has exceeded since the last calibration. This time period represents a maximum amount of time allotted between successive calibrations. For instance, even if the temperature delta did not exceed the threshold (representing that there is stability in temperature), the routine attempts to perform at least one calibration every given amount of time, e.g., the given amount of time being the maximum amount of time. In some embodiments, this maximum amount of time can be dynamically updated based on the AI model's output (e.g., output of the AI model referred to at 328, see also FIG. 4, 428). For instance, this maximum amount of time can be adjusted based on a direct output of the reinforcement learning model, used in computing the frequency of calibration as described above.

If the time period since the last calibration has not exceeded the maximum amount of time, the routine returns to idling at 302. If the time period since the last calibration has exceeded the maximum amount of time, the routine proceeds to calibration, e.g., proceeds to 316.

At 316, the routine again checks whether a non-interruptible operation is about to start. For example, because such operations may be driven based on interrupts, the routine rechecks whether another interruptible operation is about start before proceeding with the calibration. If the routine determines that a non-interruptible operation is about to start, the routine proceeds to 306, waiting for that non-interruptible operation to finish. If the routine determines that no non-interruptible operation is about to start, the routine proceeds to 318.

At 318, the routine pauses one or more interruptible operations in progress in the computer system or device. For example, a memory controller may save the current state of an interruptible operation (such as background scrubbing of memory), stop temporarily that interruptible operation. The memory controller then may restore the saved state when the interruptible operation is to be resumed.

At 320, calibration is performed. For example, the routine runs DQS alignment, which adjusts a timing of a data strobe (DQS) signal relative to data lines (DQ) of the memory. As described above, a DQS alignment process is technically known as DQS Interval Offset in the Joint Electron Device Engineering Council (JEDEC) standard. It includes performing the following steps: 1. Send a Multi-Purpose Command (MPC) to initiate the DQS Interval Oscillator; 2. Either wait a pre-determined amount of calibration time—or—issue an MPC to manually stop the calibration after a desired amount of time; 3. Issue two Mode Register Read (MRR) operations to extract the calibration results from the DRAM devices; 4. Perform the required propagation updates to the DQS transceiver circuitry on the host chip based on the information provided by the results obtained from the two MRR operations.

At 322, the routine records or logs data associated with the calibration such as data results. Data that is logged can include cumulative count of various data from recalibrations. Examples include, but are not limited to, log entry for each of last X number of recalibrations, where X can be configurable. For example, log entry for each of last 24 recalibrations can be logged or recorded, which can include the type of trigger (e.g., temperature or time-based), count of tracking executions since the occurrence of the previous recalibration, and DIMM temperature. More examples of data that is logged can include correction information for all of the DRAM devices or a subset of DRAMs, (e.g., 3 most-affected DRAMs), such as correction amount, rank, DRAM index, and chip temperature.

The results are also used to update the learning of the AI model at 326. For example, log information or results from alignment operations (e.g., every DQS alignment performed) can be used by the AI model in addition to monitored environmental and other aspects of a computer system or device. The AI model may use all those different types of information to learn and make decisions.

At 324, the routine resumes the interruptible operations that were paused at 318, e.g., resumes the applications that were running in the computer system or device. For instance, the saved state of the interruptible operations are restored. The routine then proceeds to idling at 302.

In some embodiments, recalibration results are incorporated into runtime diagnostics to proactively identify suspect memory devices before actual memory errors occur. For example, the logged results track the drift at a device level, and therefore, the recalibration results can be used to predict which DRAMs have drifted far enough such that they are in imminent risk of providing corrupted data over the DDR interface. Depending on how many DRAMs are at risk, the following known techniques can be pre-emptively deployed: Deploying ECC chip marks (also known as ECC chip kill correction); Deploying spare DRAMs; If more DRAMs are at risk than can be handled with chip marks and spare DRAMs, customer workloads can be moved to another working memory in a subject computer system, such that those workloads are no longer at risk of imminent uncorrectable memory corruption. For example, the results from the calibrating are used to proactively identify suspect memory devices and pre-emptively deploy a mitigation action that minimizes workloads being exposed to a risk of memory corruption.

FIG. 4 is yet another flow diagram illustrating a method in some embodiments. The method provides for memory recalibration, and can be run or performed by one or more computer or hardware processors, e.g., a memory controller, a memory buffer chip, and/or another. An example of a hardware processor is a memory controller. For example, a memory controller may perform DQS alignment, which aligns the Data Strobe (DQS) signal with the Data (DQ) signals on a DDR memory interface, to provide for accurate data sampling and reliable data transfer between a computer processor and memory modules. The method in this embodiment employs an AI model such as a reinforcement learning model to dynamically trigger the calibration based on real time learning.

The method employs an AI model such as a reinforcement learning model described above to dynamically update a timer used to wakes up a routine for performing memory calibration, to dynamically update a temperature threshold, and/or dynamically update a maximum amount of time between consecutive calibrations, which are used to determine whether memory recalibration should be performed. As described above, the AI model may interface with a BMC or like specialized processor, in updating various thresholds and/or triggers.

At 402, a processing idles, waiting for a timer to trigger. This processing can be in a form of a thread or a process that is running in a background, for example, as a daemon process, or another process on a computer of another processing device. Triggering of the timer wakes up a routine, e.g., a firmware routine, e.g., for performing memory calibration such as DQS alignment. In some embodiments, this timer may be updated based on outputs generated by an AI model, e.g., the AI model referred to at 428, and also in FIG. 3 at 328.

At 404, the routine determines whether a non-interruptible operation is running or in progress in a computer system or device. Examples of non-interruptible operations include priority operations such as a recovery operation, a repair operation, or another type of operation that may be critical for proper running or maintenance of the computer system or device. In some embodiments, a non-interruptible operation may be running on a processor of the computer system, and/or a memory buffer chip, and/or elsewhere associated with the computer system and/or device.

At 406, if a non-interruptible operation is in progress, the routine waits for the non-interruptible operation to complete. The routine resumes calibration or recalibration operation after the non-interruptible operation completes, e.g., proceeds to 416.

At 408, if no non-interruptible operation is in progress, the routine reads the temperature of the computer system or device. The temperature readings, for example, can be obtained from various sensors that measure temperature of a computer system or device. The routine reads or obtains readings from sensors, such as temperature sensors, associated with one or more memory devices. By way of example, the thermal sensors that participate in the process can be a combination of discrete temperature sensors on the memory DIMMs and embedded thermal sensors in the memory buffer chips.

At 410, the routine determines whether there is an error in reading the temperature. If an error is encountered in reading the temperature, the routine proceeds to another check at 414. An error may be detected if a temperature sensor is not working properly, or a function that is collecting temperature data is not functioning properly, or another improper functioning of components involved in obtaining temperature data. Since in such situations, there is no valid temperature data, the routine skips the determining of whether to perform a calibration based on a temperature reading.

At 412, if no error is encountered in reading the temperature, the temperature that is read (current temperature) is compared to a past temperature data, e.g., historic temperature. The difference (referred to as temperature delta) between the current temperature and the historic temperature is compared to a threshold. The threshold is a dynamic value that is updated based on an AI model's output, for example, as shown at 428. For instance, the AI model can be a reinforcement learning model, described above, which continuously learns optimal threshold values based on the state of an environment, taking an action, and reward resulting from the action taken. In some embodiments, the threshold (also referred to above as temperature threshold) can be determined or computed value on computing value P, as described above with reference to FIG. 3.

If the temperature delta exceeds the threshold, the routine proceeds to calibration, e.g., proceeds to 416. If the temperature delta does not exceed the threshold, the routine proceeds to another test or check at 414.

At 414, the routine determines whether a time period has exceeded since the last calibration. This time period represents a maximum amount of time allotted between successive calibrations. For instance, even if the temperature delta did not exceed the threshold (representing that there is stability in temperature), the routine attempts to perform at least one calibration every given amount of time, e.g., the given amount of time being the maximum amount of time. In some embodiments, this maximum amount of time can be dynamically updated based on the AI model's output, for example, as shown at 428. An example of such AI model is a reinforcement learning model as described above, which learns based on the state of the environment, taking an action, and a reward associated with the action taken. Multiple episodes of learning steps (state, action, reward) are performed. As described above, in some embodiments, the frequency of calibration is determined based on the average of the time between last N number of attempts to perform an alignment, where N is an integer, which may be configurable or predefined. For example, the frequency of calibration can be determined as the average of the time between the last 100 attempts to perform an alignment. In some embodiments, similar P formulation described above can be applied to adjust the time to trigger at 402 and also the maximum time count at 414 based on the AI model (e.g., reinforcement learning model) output. Other methodologies can also be used in determining the adjustment values.

If the time period since the last calibration has not exceeded the maximum amount of time, the routine returns to idling at 402. If the time period since the last calibration has exceeded the maximum amount of time, the routine proceeds to calibration, e.g., proceeds to 416.

At 416, the routine again checks whether a non-interruptible operation is about to start. For example, because such operations may be driven based on interrupts, the routine rechecks whether another interruptible operation is about start before proceeding with the calibration. If the routine determines that a non-interruptible operation is about to start, the routine proceeds to 406, waiting for that non-interruptible operation to finish. If the routine determines that no non-interruptible operation is about to start, the routine proceeds to 418.

At 418, the routine pauses one or more interruptible operations in progress in the computer system or device. For example, a memory controller may save the current state of an interruptible operation (such as background scrubbing of memory), stop temporarily that interruptible operation. The memory controller then may restore the saved state when the interruptible operation is to be resumed.

At 420, calibration is performed. For example, the routine runs DQS alignment, which adjusts a timing of a data strobe (DQS) signal relative to data lines (DQ) of the memory. As described above, a DQS alignment process is technically known as DQS Interval Offset in the Joint Electron Device Engineering Council (JEDEC) standard. It includes performing the following steps: 1. Send a Multi-Purpose Command (MPC) to initiate the DQS Interval Oscillator; 2. Either wait a pre-determined amount of calibration time—or—issue an MPC to manually stop the calibration after a desired amount of time; 3. Issue two Mode Register Read (MRR) operations to extract the calibration results from the DRAM devices; 4. Perform the required propagation updates to the DQS transceiver circuitry on the host chip based on the information provided by the results obtained from the two MRR operations.

At 422, the routine records or logs data associated with the calibration such as data results. Data that is logged can include cumulative count of various data from recalibrations. Examples include, but are not limited to, log entry for each of last X number of recalibrations, where X can be configurable. For example, log entry for each of last 24 recalibrations can be logged or recorded, which can include the type of trigger (e.g., temperature or time-based), count of tracking executions since the occurrence of the previous recalibration, and DIMM temperature.

More examples of data that is logged can include correction information for all the DRAM devices or a subset of DRAMs, (e.g., 3 most-affected DRAMs), such as correction amount, rank, DRAM index, and chip temperature.

In some embodiments, recalibration results are incorporated into runtime diagnostics to proactively identify suspect memory devices before actual memory errors occur. For example, the logged results track the drift at a device level, and therefore, the recalibration results can be used to predict which DRAMs have drifted far enough such that they are in imminent risk of providing corrupted data over the DDR interface. Depending on how many DRAMs are at risk, the following known techniques can be pre-emptively deployed: Deploying ECC chip marks (also known as ECC chip kill correction); Deploying spare DRAMs; If more DRAMs are at risk than can be handled with chip marks and spare DRAMs, customer workloads can be moved to another working memory in a subject computer system, such that those workloads are no longer at risk of imminent uncorrectable memory corruption. For example, the results from the calibrating are used to proactively identify suspect memory devices and pre-emptively deploy a mitigation action that minimizes workloads being exposed to a risk of memory corruption.

The results are also used to update the learning of the AI model at 426. For example, log information or results from alignment operations (e.g., every DQS alignment performed) can be used by the AI model in addition to monitored environmental and other aspects of a computer system or device. The AI model may use all those different types of information to learn and make decisions.

At 424, the routine resumes the interruptible operations that were paused at 418, e.g., resumes the applications that were running in the computer system or device. For instance, the saved state of the interruptible operations are restored. The routine then proceeds to idling at 402.

In some embodiments, a system and/or method determines execution of memory recalibration procedures while concurrently running functional traffic, where a reinforcement learning model is employed to predict optimal triggering of the memory recalibration procedures based on factors such as time, temperature, voltage, memory bandwidth, functional traffic, past recalibration results, devices parts characterization data, and/or other factors. Such optimal triggering occurs frequently enough to avoid memory errors but not so frequently as to negatively impact system performance.

In some embodiments, the execution of memory recalibration procedures is dynamic, in that based on the predicted triggering of the reinforcement learning model, the frequency or timing of the execution of memory recalibration can vary over time. In some embodiments, such dynamic execution of memory recalibration procedures can be tuned to specific memory devices in a computer system or device (e.g., DRAMs, DIMMs, and/or others) based on machine learning of device characterization data.

In some embodiments, the execution of memory recalibration procedures is appropriately prioritized with other concurrent system activities such as non-interruptible repair and/or recovery actions and interruptible activities such as background memory scrubbing. For example, as described above, a system and/or method perform a periodic DQS interval offset calibration concurrently with functional traffic, and in an efficient manner that allows for required background maintenance activity. The system and/or method optimizes a plurality of anticipated calibration and maintenance actions in response to future memory requirements and concurrently manages calibration with mainline traffic and background activity in a performance optimized manner.

In some embodiments, recalibration results are incorporated into runtime diagnostics to proactively identify suspect memory devices before actual memory errors occur. For example, the logged results track the drift at a device level, and therefore, the recalibration results can be used to predict which DRAMs have drifted far enough such that they are in imminent risk of providing corrupted data over the DDR interface. Depending on how many DRAMs are at risk, the following known techniques can be pre-emptively deployed: Deploying ECC chip marks (also known as ECC chip kill correction); Deploying spare DRAMs; If more DRAMs are at risk than can be handled with chip marks and spare DRAMs, customer workloads can be moved to another working memory in a subject computer system, such that those workloads are no longer at risk of imminent uncorrectable memory corruption. For example, the results from the calibrating are used to proactively identify suspect memory devices and pre-emptively deploy a mitigation action that minimizes workloads being exposed to a risk of memory corruption.

In some embodiments, a method and/or system determines execution of memory recalibration procedures where thermal monitoring is a factor in determining the triggering of a memory recalibration. In some embodiments, a time-based governor is provided to ensure a minimum level of periodic recalibration regardless of thermal stability.

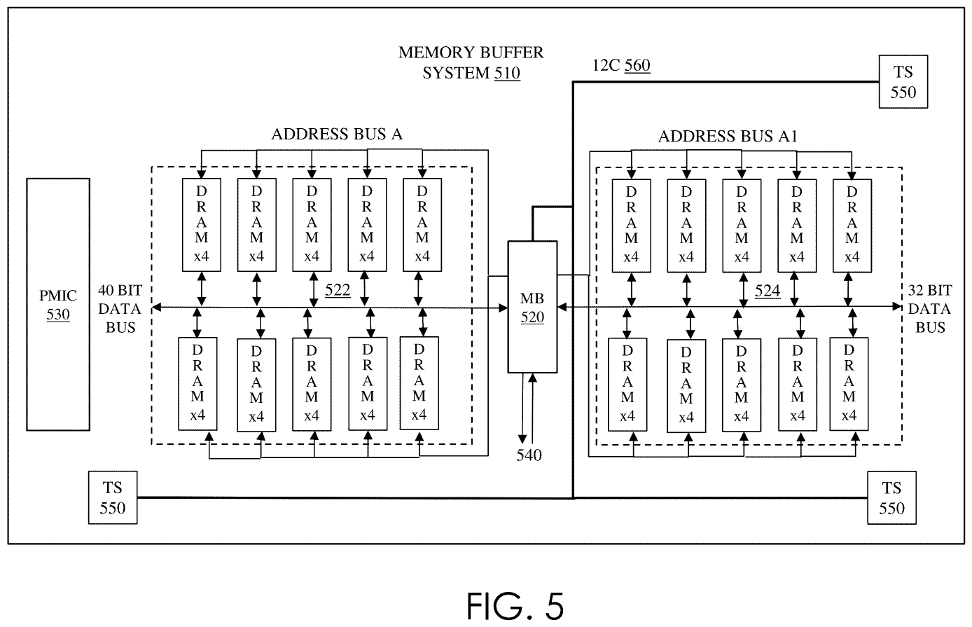

FIG. 5 illustrates a block diagram of one example of a memory buffer system configured in a unified memory buffer topology with a dedicated connection to an interface such as High Speed Serial (HSS) interface. In one example, a memory buffer system 510 may include multiple circuit elements, including, but not limited to, multiple DRAM devices and a memory buffer chip configured in a unified memory buffer topology. In one example, memory buffer system 510 is illustrated with multiple sets of DRAM devices illustrated by a DRAM set 522 and DRAM set 524, which may be implemented with DRAM devices, a memory buffer chip (MB) 520, and a Power Management Integrated Circuit (PMIC) 530 for driving the power grid of memory buffer system 510.

In one example, each set of DRAM devices illustrated may include multiple DRAM chips. For example, DRAM set 522 illustrates 10 DRAM chips connected on a 40 bit data bus to MB 520 and DRAM set 524 illustrates 8 DRAM chips connected on a 32 bit data bus to MB 520. In one example, MB 520 may control an address bus, illustrated as “address bus A” to the DRAM chips in DRAM set 522 and as “address bus A1” to the DRAM chips in DRAM set 524.

In one example, MB 520 may include a DDR read path for connecting memory buffer system 510 to a host through an HSS interface, illustrated by connections 540. In additional or alternate embodiments, MB 520 may include additional or alternate components and connections.

In one example memory buffer system 510 also employs one or more thermal sensors 550 to monitor the temperature of the DIMM. These thermal sensors communicate with the memory buffer chip 520 via a communication bus such as I2C Bus 560, but one skilled in the art can envision this being other types of communications busses such as I3C, Server Message Block (SMB) and the like.

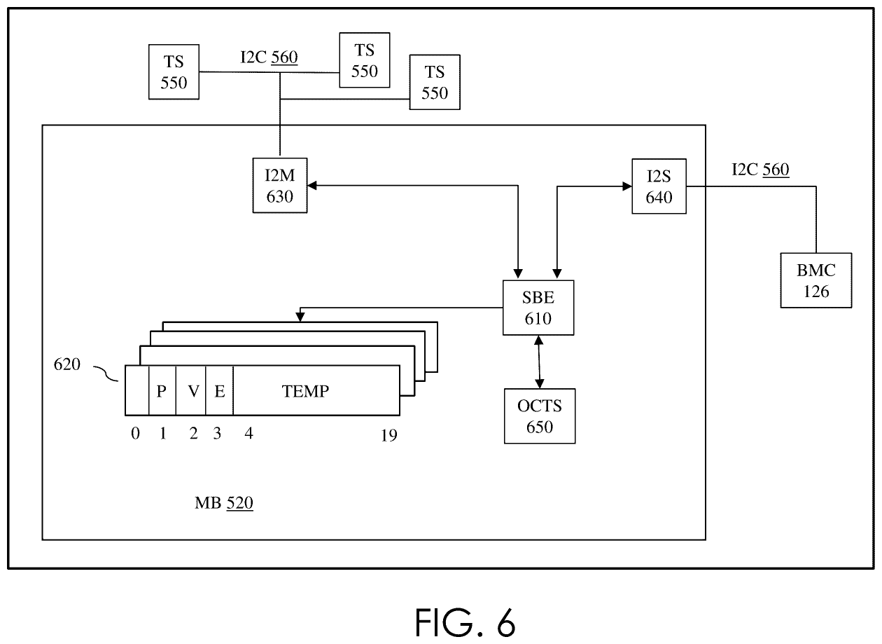

FIG. 6 illustrates a process by which the memory buffer chip 520 communicates with the thermal sensors 550 and obtains the thermal information, e.g., used in processing shown at 312 (FIG. 3) and/or 412 (FIG. 4) of the concurrent maintenance routine, in some embodiments. In some embodiments, memory buffer chip 520 employs a secure boot engine (SBE) 610 which is a microcontroller capable of running firmware initialization, security and maintenance processes. The SBE 610 communicates with the overall system by way of the BMC 126 using an I2C bus 560 connected to an I2S controller 640 on the memory buffer chip 520. This permits the SBE 610 to exchange information with the BMC 126 for purposes of loading, altering, executing, monitoring and terminating procedures running in the SBE 610. In some embodiments, the techniques disclosed herein may use BMCs or Service Elements (SE) which are dedicated “computers” whose job it is to manage and maintain the main computer system. BMCs are controllers that are loaded with firmware and applications that run continuously monitoring the main computer system and intervening to perform required maintenance tasks. In some embodiments, the techniques disclosed herein may also have facilities embedded in the processor and memory chips to provide hardware assists to these SE and BMC firmware applications.

Upon completing initialization, the SBE 610 runs a dedicated process that continually polls each thermal sensor 550 on the DIMM via the I2M controller 630 to obtain the latest temperature data. The SBE 610 polls each sensor in turn at a fixed interval. The thermal information from each sensor is deposited into an associated thermal sensor register 620 where it can be accessed by the DQS alignment routine, e.g., at 312 (FIG. 3) and/or 412 (FIG. 4). In addition to the DIMM thermal sensors 550, the memory buffer chip 520 also contains its own on-chip thermal sensor (OCTS) 650. The SBE 610 can also poll this OCTS to obtain and store the chip temperature in one of the thermal sensor registers 620. In some embodiments, there is one thermal sensor register 620 for each DIMM thermal sensor 550 and the OCTS 650. Briefly, I2M is a I2C Controller and I2S is a I2C Target or Responder. In some embodiments, I2M initiates communication on the I2C bus, controls the clock signal (SCL), and transmits and receives data to and from target devices. I2S responds to commands from the controller (I2M), transmits and receives to and from the controller, and has a unique 7-bit or 10-bit address to distinguish it on the bus.

In some embodiments, the thermal sensor registers 620 comprise 19 bits of information wherein the temperature is represented in a 16 bit binary code that allows for extreme accuracy. The thermal sensor registers 620 also contain 3 status bits. The presence bit (P) indicates that the thermal sensor 550 or OCTS 650 associated with that register is physically present and functional in that system. The valid bit (V) indicates that the current thermal reading is a valid temperature. The error bit (E) signifies that some type of error occurred while polling the sensors or accessing the register and thus may require attention before the included thermal information can be relied upon.

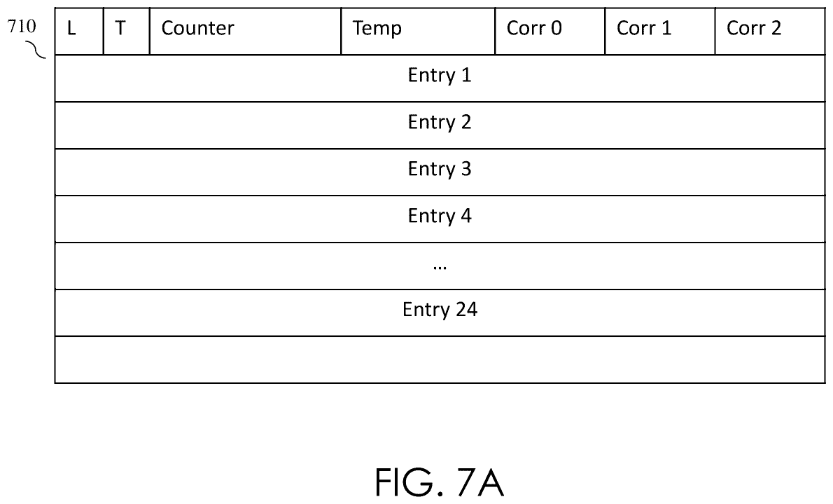

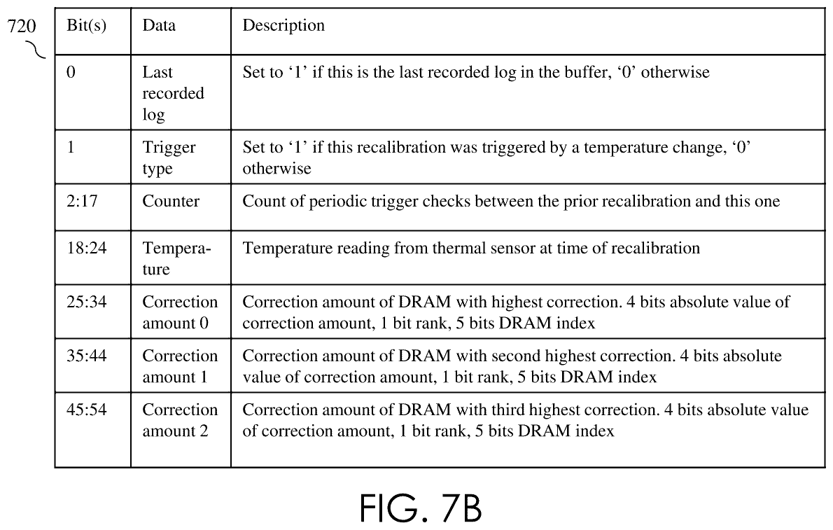

FIGS. 7A-7B illustrate an example log in some embodiments, for example, a formatted log of the DQS alignment results from the processing at 322 (FIG. 3) and/or 422 (FIG. 4) of the concurrent maintenance routine. A buffer, referred to as a rolling results buffer 710, stores the most recent entries, e.g., the most recent 24 entries. The rolling results buffer 710 includes a number of fields, e.g., 7 fields, associated with an entry or each entry. An entry is recorded every time a DQS alignment is performed. The entry table 720 describes each of the 7 fields that comprise an individual entry in the rolling results buffer 710. Bit 0 is set if this is the last recorded log. Bit 1 indicates whether the calibration was performed due to the thermal threshold being exceeded at 312 (FIG. 3) and/or 412 (FIG. 4), or due to the timer being exceeded at 314 (FIG. 3) and/or 414 (FIG. 4). Bits 2:17 are a 16 bit counter indicating how many triggers have occurred (e.g., 302 in FIGS. 3 and/or 402 in FIG. 4) since the last calibration. For example, if the timer at 312 (FIG. 3) and/or 412 (FIG. 4) is set to 1 minute, and the trigger timer at 302 in FIGS. 3 and/or 402 in FIG. 4 is set to 1 second, then a calibration is guaranteed to happen every 60 seconds or every 60 “wake up” triggers (at 302 in FIGS. 3 and/or 402 in FIG. 4). Thus, if the calibration occurred because of the timer being exceeded at 312 (FIG. 3) and/or 412 (FIG. 4), this counter field would show 60 whereas if the calibration was triggered due to temperature being exceeded, this counter would likely show a value less than 60. If calibrations were repeatedly being performed due to exceeding the temperature threshold, and this counter field indicated the alignments were being performed in close proximity, that might indicate thermal instability in the system. Bits 18:24 indicate the temperature read out of one of the thermal sensor registers 620.

Bits 25:54 are used to record the alignment results. Some embodiment permit tracking a fixed number of devices, e.g., only 3 devices, at a time due to storage limitations. Thus, when a calibration completes, the procedure reviews the results for all of the DRAM devices that underwent calibration and sorts them from worst to best. The 3 worst devices (e.g., those that required the most offset correction or the most “alignment”) are selected for logging. Each device is allocated 10 bits wherein 4 bits indicate how much correction (alignment) was applied, 1 bit denotes the rank identifier (ID) on the DIMM, and 5 bits identify the DRAM device on the DIMM. One skilled in the art can appreciate how this same information could be organized in various ways and extended to allow for tracking of all DRAM devices in the system at all times.

In some embodiments, the maintenance and/or calibration described above can extend beyond memory alignment such as DQS Interval Offset (DQS alignment) and thermal-based memory calibrations. Rather, concurrent maintenance operations on a device while functional traffic is occurring can be performed based on other factors. For example, while some embodiments perform DQS Interval Offset periodic calibration where the calibration is triggered based on thermal data, other embodiments can encompass using different or additional factors. For example, other forms of calibration may be more susceptible to environmental factors other than temperature, such as voltage or another factor. For instance, at 210 in FIG. 2, the environmental threshold criterion need not be limited to temperature threshold, and at 212 in FIG. 2, the AI model can be used to update threshold other than the temperature threshold. Likewise, at 308 in FIG. 3 and at 408 in FIG. 4, data acquisition such as sensor readings need not be limited to temperatures data, rather readings or information about other factors can be acquired. It follows that at 312 in FIG. 3 and at 412 in FIG. 4, the comparison can be based on one or more of those other factors and thresholds associated with those other factors. For example, at 308 in FIGS. 3 and/or 408 FIG. 4, acquiring readings can include obtaining readings from voltage monitors, and at 312 (FIG. 3) and/or 412 (FIG. 4), a comparison can be performed against a voltage threshold to determine whether to trigger a calibration. Further, those maintenance operations can be a variety of operations, other types of concurrent operations (e.g., outside of memory area), for instance, not limited to calibrations. The maintenance operations that are types of calibrations also may use information other than or in addition to temperature, e.g., sensitive to factors other than temperature.

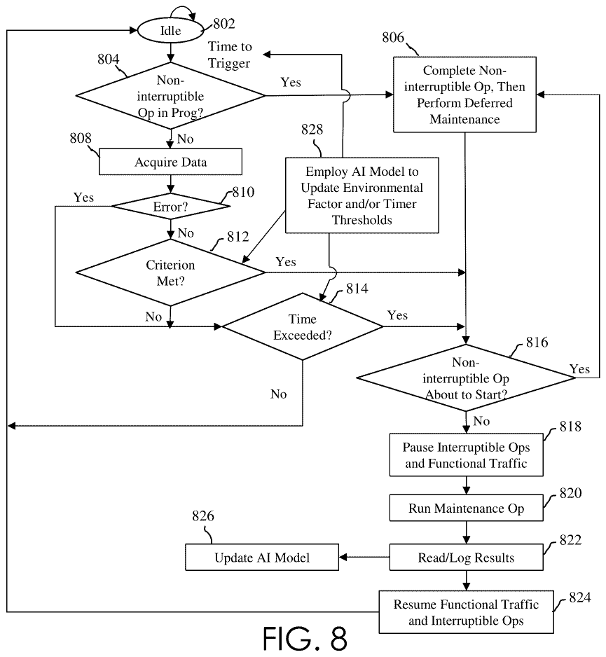

FIG. 8 illustrates a flow of a method that performs a device or a processing component maintenance based on one or more factors, e.g., other than or in addition to thermal information in some embodiments. The method provides for concurrent maintenance of a device and/or computer component while functional traffic is occurring, e.g., on a computer system or like device, and can be run or performed by one or more computer or hardware processors, e.g., a processor, a memory controller, a memory buffer chip, and/or another. A device or computer component can be a component of a computer system such as a memory device, a firmware and/or software of a computer system. The method considers a timer as well as environmental monitoring to determine whether to perform a maintenance operation. The method in this embodiment employs an AI model such as a reinforcement learning model described above to dynamically trigger the maintenance operation based on real time learning.

The method also employs an AI model such as a reinforcement learning model described above to dynamically update a timer used to wakes up a routine for performing the maintenance operation, and also to dynamically update an environment factor threshold, which are used to determine whether the maintenance operation should be performed. As described above, the AI model may interface with a specialized processor such as a BMC, or another processor in updating various thresholds and/or triggers.

At 802, a processing idles, waiting for a timer to trigger. This processing can be in a form of a thread or a process that is running in a background, for example, as a daemon process, or another process on a computer of another processing device. The time intervals to trigger this timer (e.g., when to trigger the timer) is controlled based on the AI model as shown at 828, for example, a reinforcement learning model that learns the optimal times to trigger this timer. For instance, based on the AI model's output, the time intervals are dynamically updated. The timer triggers at intervals of time specified according to the AI model's output. Triggering of the timer wakes up a routine, e.g., a firmware routine, e.g., for performing a maintenance operation on a computer component.

At 804, the routine determines whether a non-interruptible operation is running or in progress in a computer system or device. Examples of non-interruptible operations include priority operations such as a recovery operation, a repair operation, or another type of operation that may be critical for proper running or maintenance of the computer system or device.

At 806, if a non-interruptible operation is in progress, the routine waits for the non-interruptible operation to complete. The routine resumes maintenance operation after the non-interruptible operation completes, e.g., proceeds to 816.

At 808, if no non-interruptible operation is in progress, the routine acquires sensor data or other data associated with one or more computer components, e.g., one or more devices or computer components being maintained in the computer system or device. For example, the routine determines current data (or information) associated with a computer component, the computer component being associated with at least one processor of the computer system or device. For instance, the computer component may be one or more memory devices, and the routine may obtain readings from sensors associated with such one or more memory devices. For example, in an example use case where a maintenance of a device such as a memory device is to be performed based on an environmental factor such as voltage level, the routine may acquire voltage readings from voltage monitors.

By way of another example, a maintenance operation can be a maintenance for a processing component such as an artificial intelligence (AI) model running on a processor (referred to as a transactional AI model for simplicity of explanation). Note this transactional AI model is a used as an example of a type of a computer component that is being maintained, and for which the AI model (reinforcement learning model described above) is used for updating thresholds (e.g., criterion (812) and timer triggers (802), and maximum time counts (814)). For example, a processor may interact with an AI engine to perform AI training and inferencing on transactional workloads associated with this transactional AI model. In an example use case, the transactional AI model may be performing real time security detection on financial transactions. Historically, this entails performing an initial training of the AI model followed by real time inferencing of the transactions. An environment may exist that performs periodic updating and training of the transactional AI model (also known as Online Learning), and thereby requiring temporary interruption of the transactional workload. In this scenario, the new input information for the model (e.g., legal documentation, transactional records, news feeds, images, social media content, etc.), updated weights for the underlying neural network, data to change the type of model, etc., can be acquired at 808. In this example scenario, the maintenance operation performed can be the retraining of the transactional AI model.

At 810, the routine determines whether there is an error in reading or obtaining the sensor data or information. If an error is encountered in reading or obtaining the sensor data or information, the routine proceeds to another check at 814. An error may be detected if a sensor is not working properly, or a function that is collecting sensor data is not functioning properly, or another improper functioning of components involved in obtaining or collecting sensor data or information. Since in such instances, there is no valid sensor data or information, the routine skips the determining of whether to perform a maintenance based on this sensor reading or acquired data.

At 812, if no error is encountered in reading or obtaining the sensor data or information, the routine determines whether a criterion is met by the obtained sensor data or information. For example, the criterion can be that the current sensor data or information meets a threshold value, which is configurable. For instance, the sensor data that is read or obtained is compared to a past sensor data, e.g., historic sensor data. The difference (referred to also as sensor data delta) between the current sensor data and the historic sensor data is compared to a threshold.

For instance, the AI model can be a reinforcement learning model, described above, which continuously learns the optimal threshold values based on the state of an environment, taking an action and associated reward. In some embodiments, optimal criteria or thresholds can be determined through computing a value, referred to as P for simplicity of explanation, for instance, optimal environmental factor criterion (e.g., threshold) and trigger times can be found through computing value P. P represents a fraction of the current value to use as the adjustment for a new value. When the AI model chooses action to perform a maintenance operation, the AI model or a controller computes P as, P=1/(log (1+R)), where R is the value of the computed reward. For example, consider a temperature threshold as the environmental factor criteria. Consider also an initial threshold of 5 degrees Celsius (C). The AI model computes a reward (R), e.g., of 5. This R value, 5, can be plugged into the P formula, resulting in P=1.28. This is the fraction (or percentage) of the current value to use for the adjustment. In some embodiments, a program (e.g., firmware or software) running on a computer system can perform this updating. For example, such a program multiplies P by the current value (hence 1.28×5 degrees C.) and gets a new threshold value of 6.4 degrees C. Hence, at 812, the routine compares the temperature delta against 6.4 (not 5), e.g., in the case the environmental factor being used is temperature. Consider that the process has run for a while and the AI model produces a new R of 60. That new R value in turn results in a different value of P, i.e., P=0.56 (when 60 is used in the above P formula). Consequently, the program adjusts the current temperature threshold by 0.56 (6.4×0.56) to get a new temperature threshold of 3.58. In some embodiments, as illustrated by the above example, such a formulation (e.g., P formulation) can adjust the threshold and converge on a stable value, for example, an optimal value. In some embodiments, a program (e.g., firmware or software) running on a computer system can perform this updating or adjusting of the threshold. In some other embodiments, an administrator or the like can manually update the threshold based on the output of the AI model. For instance, a user, an operator or a programmer, may enter via an interface such as a user interface or via a program an update for such threshold or another criterion. Similar P formulation concept can be applied to adjust the time to trigger at 802 and also the maximum time count at 814. Other methodologies can also be used in determining the adjustment values.

In some embodiments, the historic sensor data can be the sensor data taken at last maintenance procedure. In some other embodiments, the historic sensor data can be an average of sensor data taken in the past N number of maintenance procedures, where N is a configurable number. In yet some other embodiments, the sensor data can be an average sensor data taken in the past T time window, where T is a configurable number. Other methods can be employed to establish the historic sensor data, to which the current sensor data is compared to compute the delta.

In another use case example where the processing component of computer component to be maintained is another AI model such as the transactional AI model described above with reference to 808, the new input information for the model, e.g., legal documentation, transactional records, news feeds, images, social media content, etc., updated weights for the underlying neural network, and/or data to change the type of model, etc., acquired at 808, can be compared against the existing training information at 812 using a differential criterion to determine a criterion of whether or not the input information has changed sufficiently enough to warrant retraining the transactional AI model. Sufficiency of change can be measured based on a threshold, e.g., a threshold differential, which can be updated or adjusted based on the AI model (e.g., the reinforcement learning model described above) output. If the criterion is met, e.g., the difference in the current data and past data (existing training information) meets a threshold differential (exceeds a threshold), then the routine proceeds to 816.

If the criterion is met, the routine proceeds to maintenance, e.g., proceeds to 816. If the criterion is not met, the routine proceeds to another test or check at 814.

At 814, the routine determines whether a time period has exceeded since the last maintenance. This time period represents a maximum amount of time allotted between successive maintenance operations. For instance, the routine determines a time elapsed since a last previous maintenance of the computer component. For instance, even if the sensor data delta did not exceed the threshold (representing that there is stability in a condition being measured by the sensor data), the routine attempts to perform at least one maintenance operation every given amount of time, e.g., the given amount of time being the maximum amount of time. In some embodiments, this maximum amount of time can be dynamically updated based on the AI model's output. For instance, this maximum amount of time can be adjusted based on a direct output of the reinforcement learning model. By way of example, similar formulation such as the P formulation described above at 812 can be applied to adjusting the maximum amount of time.

If the time period since the last maintenance operation has not exceeded the maximum amount of time, the routine returns to idling at 802. If the time period since the last maintenance operation has exceeded the maximum amount of time, the routine proceeds to maintenance, e.g., proceeds to 816. For instance, performing of a maintenance of the computer component is triggered based on at least one of: the current data meeting a criterion, and the time elapsed being greater than a maximum time count.

At 816, the routine again checks whether a non-interruptible operation is about to start. For example, because such operations may be driven based on interrupts, the routine rechecks whether another interruptible operation is about start before proceeding with the actual maintenance operation. If the routine determines that a non-interruptible operation is about to start, the routine proceeds to 806, waiting for that non-interruptible operation to finish. If the routine determines that no non-interruptible operation is about to start, the routine proceeds to 818.

At 818, the routine pauses one or more interruptible operations in progress in the computer system or device. For example, a controller or processor operation may save the current state of an interruptible operation (such as background scrubbing of memory), stop that operation, then restore the saved state when the interruptible operation is to be resumed.

At 820, maintenance operation is performed. For example, if the maintenance operation is calibration operation on a memory device, the routine runs a calibration operation such as DQS alignment, which adjusts a timing of a data strobe (DQS) signal relative to data lines (DQ) of the memory. By way of another example, the maintenance operation can be a maintenance for a processing component such as a transactional artificial intelligence (AI) model running on a processor, e.g., an example of which is described above at 812. For example, a processor may interact with an AI engine to perform AI training and inferencing on transactional workloads. In an example use case, the transactional AI model may be performing real time security detection on financial transactions. Historically, this entails performing an initial training of the transactional AI model followed by real time inferencing of the transactions. An environment may exist that performs periodic updating and training of the transactional AI model (also known as Online Learning), and thereby requiring temporary interruption of the transactional workload. In this scenario, the new input information for the transactional model (e.g., legal documentation, transactional records, news feeds, images, social media content, etc.), updated weights for the underlying neural network, data to change the type of transactional model, etc., acquired at 808, can be compared against the existing training information at 812 using a differential criterion to determine whether or not the input information has changed sufficiently enough to warrant retraining the transactional AI model. If so, the routine at 820 can trigger the interruption of the transactional workload to accomplish the retraining of the transactional AI model. In this example scenario, the maintenance operation performed can be the retraining of the transactional model.

For example, as described above, in some embodiments, the computer component includes a memory device, the current data includes voltage reading obtained from a voltage monitor associated with the at least one processor, the criterion includes whether a difference between the voltage reading and a past voltage reading exceeds a voltage threshold, and the maintenance operation includes calibrating the memory device.

By way of another example, as described above, in some embodiments, the computer component includes another AI model, the current data includes data associated with training of said another AI model, and the criterion includes whether a difference between the current data and prior used training data exceeds a differential threshold, and the maintenance operation includes retraining said another AI model

At 822, the routine records or logs data associated with the maintenance operation performed, such as data results. Data that is logged can include cumulative count of various data from the maintenance operation. Examples include, but are not limited to, log entry for each of last X number of maintenance operation, where X can be configurable. For example, a log entry for each of last 24 maintenance operation can be logged or recorded, which can include the type of trigger (e.g., sensor data delta or time-based), count of tracking executions since the occurrence of the previous maintenance operation, and sensor data.

In some embodiments, the results from performing the maintenance operation are used to proactively identify suspect computer components and pre-emptively deploy a mitigation action that minimizes workloads being exposed to risk errors occurring in the computer components.

The results are also used to update the learning of the AI model at 826. For example, log information or results from the maintenance operation can be used by the AI model in addition to monitored environmental and other aspects of a computer system or device. The AI model may use all those different types of information to learn and make decisions.

At 824, the routine resumes the interruptible operations that were paused at 818, e.g., resumes the applications that were running in the computer system or device. For instance, the saved state of the interruptible operations are restored. The routine then proceeds to idling at 802.

As described above and shown at 828, an AI model such as a reinforcement learning model is employed in some embodiments, where the output of the reinforcement learning model is used to update one or more of the time to trigger (described with reference to 802), the criterion (described with reference to 812) and/or the maximum amount of time (described with reference to 814). A formulation such as the P formulation described above can be used to determine the adjustments or updates to the initial or previous set values for the time to trigger, the criterion and the maximum amount of time.

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “or” is an inclusive operator and can mean “and/or”, unless the context explicitly or clearly indicates otherwise. It will be further understood that the terms “comprise”, “comprises”, “comprising”, “include”, “includes”, “including”, and/or “having,” when used herein, can specify the presence of stated features, integers, steps, operations, elements, and/or components, but do not preclude the presence or addition of one or more other features, integers, steps, operations, elements, components, and/or groups thereof. As used herein, the phrase “in some embodiments” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A computer-implemented method comprising:
determining temperature of a memory device, the memory device coupled with at least a processor;
responsive to the temperature exceeding a threshold, triggering performing of a calibration of the memory device; and
responsive to the temperature not exceeding the threshold, determining time elapsed since a previous calibration of the memory device, and responsive to the time elapsed being greater than a maximum time count, triggering performing of the calibration of the memory device,
wherein the threshold and the maximum time count are dynamically updated based on outputs of an artificial intelligence (AI) model, the AI model learning based on environmental and performance factors associated with the processor and the memory device.

2. The computer-implemented method of claim 1, wherein the triggering of the performing of the calibration of the memory device comprises:
determining that a non-interruptible operation is in progress;
responsive to determining that the non-interruptible operation is in progress, allowing the non-interruptible operation to finish running;
pausing an interruptible operation in progress:
calibrating the memory device;
logging results from the calibrating;
updating the AI model using the results; and
resuming the interruptible operation.

3. The computer-implemented method of claim 1, wherein the determining of the temperature and the determining of the time elapsed, are performed responsive to triggering of a timer.

4. The computer-implemented method of claim 3, wherein the outputs of the AI model are used to dynamically update a trigger interval of the timer.

5. The computer-implemented method of claim 1, wherein results from the calibrating are used to proactively identify suspect memory devices and pre-emptively deploy a mitigation action that minimizes workloads being exposed to a risk of memory corruption.

6. The computer-implemented method of claim 1, wherein determining that the temperature exceeds the threshold comprises determining a temperature difference between the temperature and a temperature reading at a prior point in time, and determining that the temperature difference exceeds the threshold.

7. The computer-implemented method of claim 1, wherein determining that the temperature exceeds the threshold comprises determining a temperature difference between the temperature and an average of a number of prior temperature readings, and determining that the temperature difference exceeds the threshold.

8. The computer-implemented method of claim 1, wherein the calibrating adjusts a timing of a data strobe (DQS) signal relative to data lines (DQ) of the memory device.

9. The computer-implemented method of claim 1, wherein the environmental and the performance factors comprise time, temperature, voltage, memory bandwidth, functional traffic, past recalibration results, and parts characterization data associated with the memory device.

10. The computer-implemented method of claim 1, wherein the AI model is a reinforcement learning model, and wherein a reward function of the reinforcement learning model considers at least a total number of calibration actions taken.

11. A computer-implemented method comprising:
determining current data associated with a computer component, the computer component being associated with at least one processor;
responsive to the current data meeting a criterion, triggering performing of a maintenance of the computer component; and
responsive to the current data not meeting the criterion, determining a time elapsed since a last previous maintenance of the computer component, and responsive to the time elapsed being greater than a maximum time count, triggering performing of a maintenance of the computer component,
wherein the criterion and the maximum time count are dynamically updated based on outputs of an artificial intelligence (AI) model, the AI model learning based on environmental and performance factors associated with at least the computer component.

12. The computer-implemented method of claim 11, wherein the triggering of the performing of the maintenance of the computer component comprises:
determining that a non-interruptible operation is in progress;
responsive to determining that the non-interruptible operation is in progress, allowing the non-interruptible operation to finish running;
pausing an interruptible operation in progress:
performing a maintenance operation on the computer component;
logging results from the calibrating;
updating the AI model using the results; and
resuming the interruptible operation.

13. The computer-implemented method of claim 11, wherein the computer component includes a memory device, the current data includes voltage reading obtained from a voltage monitor associated with the at least one processor, the criterion includes whether a difference between the voltage reading and a past voltage reading exceeds a voltage threshold, and the maintenance operation includes calibrating the memory device.

14. The computer-implemented method of claim 11, wherein the computer component includes another AI model, the current data includes data associated with training of said another AI model, and the criterion includes whether a difference between the current data and prior used training data exceeds a differential threshold, and the maintenance operation includes retraining said another AI model.

15. The computer-implemented method of claim 11, wherein the AI model is a reinforcement learning model, and wherein a reward output by the AI model is used to dynamically update the criterion and the maximum time count.

16. The computer-implemented method of claim 11, wherein the determining of the current data associated with the computer component, and the determining of the time elapsed since the last previous maintenance of the computer component are performed responsive to triggering of a timer.

17. The computer-implemented method of claim 16, wherein the AI model is a reinforcement learning model, and wherein a reward output by the AI model is used to dynamically update a trigger interval of the timer.

18. A computer program product comprising:
one or more computer-readable storage media; and
program instructions stored on the one or more storage media to perform operations comprising:
determining temperature of a memory device, the memory device coupled with at least a processor;
responsive to the temperature exceeding a threshold, triggering performing of a calibration of the memory device; and
responsive to the temperature not exceeding the threshold, determining time elapsed since a previous calibration of the memory device, and responsive to the time elapsed being greater than a maximum time count, triggering performing of the calibration of the memory device,
wherein the threshold and the maximum time count are dynamically updated based on outputs of an artificial intelligence (AI) model, the AI model learning based on environmental and performance factors associated with the processor and the memory device.

19. The computer program product of claim 18, wherein the triggering of the performing of the calibration of the memory device comprises:
determining that a non-interruptible operation is in progress;
responsive to determining that the non-interruptible operation is in progress, allowing the non-interruptible operation to finish running;
pausing an interruptible operation in progress:
calibrating the memory device;
logging results from the calibrating;
updating the AI model using the results; and
resuming the interruptible operation.

20. The computer program product of claim 18, wherein the determining of the temperature and the determining of the time elapsed, are performed responsive to triggering of a timer.

21. The computer program product of claim 20, wherein the triggering of the timer is configured based on the outputs of the AI model.

22. A computer program product comprising:
one or more computer-readable storage media; and
program instructions stored on the one or more storage media to perform operations comprising:
determining current data associated with a computer component, the computer component being associated with at least one processor;
responsive to the current data meeting a criterion, triggering performing of a maintenance of the computer component; and
responsive to the current data not meeting the criterion, determining a time elapsed since a last previous maintenance of the computer component, and responsive to the time elapsed being greater than a maximum time count. triggering performing of a maintenance of the computer component,
wherein the criterion and the maximum time count are dynamically updated based on outputs of an artificial intelligence (AI) model, the AI model learning based on environmental and performance factors associated with at least the computer component.

23. The computer program product of claim 22, wherein the triggering of the performing of the maintenance of the computer component comprises:
determining that a non-interruptible operation is in progress;
responsive to determining that the non-interruptible operation is in progress, allowing the non-interruptible operation to finish running;
pausing an interruptible operation in progress;
performing a maintenance operation on the computer component;
logging results from the calibrating;
updating the AI model using the results; and
resuming the interruptible operation.

24. The computer program product of claim 22, wherein the determining of the criterion and the determining of the time elapsed, are performed responsive to triggering of a timer, and wherein the AI model is a reinforcement learning model, wherein a reward output by the AI model is used to dynamically update a triggering interval of the timer.

25. A computer system comprising:
a processor set;
a set of one or more computer-readable storage media;
program instructions, collectively stored in the set of one or more computer-readable storage media, for causing the processor set to perform the following computer operations:
determining current data associated with a computer component, the computer component being associated with at least one processor;
responsive to the current data meeting a criterion, triggering performing of a maintenance of the computer component;
responsive to the current data not meeting the criterion, determining a time elapsed since a last previous maintenance of the computer component, and responsive to the time elapsed being greater than a maximum time count, triggering performing of a maintenance of the computer component,
wherein the criterion and the maximum time count are dynamically updated based on outputs of an artificial intelligence (AI) model, the AI model learning based on environmental and performance factors associated with at least the computer component.
